(19) United States
(12) Patent Application Publication
(10) Pub. No.: US 2018/0079036 A1
(43) Pub. Date: Mar. 22, 2018

(54) SOLDER MATERIAL AND ELECTRONIC COMPONENT

(71) Applicant: NIHON DEMPA KOGYO CO., LTD., Tokyo (JP)

(72) Inventors: Toshimasa TSUDA, Saitama (JP); Daisuke NISHIYAMA, Saitama (JP); Makoto HATANO, Saitama (JP); Kei OZAKI, Saitama (JP); Tomohisa HARADA, Saitama (JP)

(73) Assignee: NIHON DEMPA KOGYO CO., LTD., Tokyo (JP)

(21) Appl. No.: 15/708,150

(22) Filed: Sep. 19, 2017

(30) Foreign Application Priority Data
Sep. 22, 2016 (JP) 2016-184922

(51) Int. Cl. B23K 35/26; H03H 9/10; H03H 9/25; B23K 35/36

(52) U.S. Cl. CPC B23K 35/262; H03H 9/1092; H05K 1/181; B23K 35/36; H03H 9/25

(57) ABSTRACT

A solder material includes 25 to 45 mass % of Sn, 30 to 40 mass % of Sb, 3 to 8 mass % of Cu, 25 mass % or less of Ag, and 1.3 to 6 mass % of In.

### CROSS REFERENCE TO RELATED APPLICATIONS

This application is based on and claims priority under 35 U.S.C. § 119 to Japanese Patent Application No. 2016-184922, filed on Sep. 22, 2016, the entire content of which is incorporated herein by reference.

### TECHNICAL FIELD

This disclosure relates to a solder material and an electronic component manufactured using this solder material.

### DESCRIPTION OF THE RELATED ART

In production of an electronic component such as a surface acoustic wave device and a crystal resonator, a solder material is heavily used. For example, when a surface acoustic wave chip or a crystal vibration chip is housed in a container to airtightly seal this container with a lid member, the solder material is used as an airtight sealing material. The electronic component thus airtightly sealed is used mounted on a wiring board. In this regard, the solder material is also used as a connection material. The electronic component thus mounted on the wiring board is sometimes molded with resin together with other components to be modularized. Also when this module is mounted on a substrate of the electronic device, the solder material is used as a connection material.

A typical example of the conventional solder material includes one consist mainly of lead and tin, and one consist mainly of gold and tin, one consist mainly of tin-copper-argentum, and similar one. The one consist mainly of tin-copper-argentum is expected since the one matches a request for lead-free and eliminates the need for using expensive gold. For example, International Publication No. WO2014/024715 discloses, as a solder material consist mainly of tin-copper-argentum, a solder material consist of antimony-argentum-copper-, at least one material selected from aluminum, iron, and titanium, and the remaining portion made up by tin.

On the other hand, the inventors according to this application have been also seriously proceeding study for a solder material including Sn (tin), Sb (antimony), Cu (copper), Ag (argentum), and In (indium). This material also has advantages such that this material matches the request for lead-free and eliminates the need for using gold.

However, the study by the inventors has proved that, in the case of this solder material, although details will be described below, there is the following problem unless the composition is properly performed.

That is, it has been proved that, when airtight sealing, for example, between the container that houses the crystal vibration chip and the lid member is performed using this solder material, a considerable low-melting-point phase occurs in the hardened solder depending on a cooling condition after soldering. This low-melting-point phase causes to generate trouble, for example, as described below. For example, the crystal resonator is, in most cases, used by being mounted on the wiring board with the solder material (the composition does not matter). Further, the crystal resonator is sometimes modularized in a state mounted on the wiring board. Therefore, for example, in the case of the crystal resonator using the solder material as the airtight sealing material, the above-described low-melting-point phase is influenced by heat when the crystal resonator is soldered to the wiring board or heat when the crystal resonator is modularized. Thus, this causes a case where an airtight sealing portion is remelted to break the airtight sealing state of the crystal resonator. Further, when the above-described low-melting-point phase occurs on a solder-bonding portion between the crystal resonator and the wiring board, remelting also occurs at this bonding portion, thus possibly causing deterioration of bonding quality between the crystal resonator and the wiring board.

A need thus exists for a solder material and an electronic component which are not susceptible to the drawback mentioned above.

### SUMMARY

According to an aspect of this disclosure, there is provided a solder material. The solder material includes 25 to 45 mass % of Sn, 30 to 40 mass % of Sb, 3 to 8 mass % of Cu, 25 mass % or less of Ag, and 1.3 to 6 mass % of In.

The foregoing and additional features and characteristics of this disclosure will become more apparent from the following embodiments considered with reference to the accompanying drawings.

### BRIEF DESCRIPTION OF THE DRAWINGS

FIG. 1 is an explanatory drawing of a first exemplary electronic component manufactured using a solder material of this disclosure.

FIG. 2 is an explanatory drawing of a second exemplary electronic component manufactured using the solder material of this disclosure.

FIG. 3 is a drawing illustrating a differential scanning calorimetry result of a solder material of a comparative example that has been hardened in a predetermined melting and cooling condition.

FIG. 4 is a drawing illustrating a differential scanning calorimetry result of a solder material of a working example that has been hardened in the predetermined melting and cooling condition similarly to the comparative example.

FIG. 5 is a drawing illustrating yield rates after sealing at crystal resonators manufactured using the solder materials of the working example and the comparative example.

FIG. 6 is a drawing illustrating a relation between a content of In and a solder wettability.

### DETAILED DESCRIPTION

The following description describes an embodiment of this disclosure with reference to the drawings. Each drawing used in the descriptions is merely illustrated schematically for understanding the disclosure. In each drawing used in the descriptions, like reference numerals designate corresponding or identical elements, and therefore such elements will not be further elaborated here. Content rates, temperatures, cooling speeds, and a similar factor described in the following embodiment are merely preferable examples within the scope of the disclosure. Therefore, the disclosure is not limited to only the following embodiment.

### 1. COOLING CONDITION THAT HARDENS SOLDER MATERIAL

An experiment by the inventors has proved that, at a solder material including Sn, Sb, Cu, Ag, and In, depending on a difference of a cooling speed for hardening after melting of the solder material, a considerable low-melting-point phase occurs in the solder after hardening.

Specifically, when the solder material is contacted to a metal having a large thermal capacity to rapidly cool the solder material immediately after the solder material is melted (the cooling speed is estimated to be 50° C./second or more), and when the solder material is cooled such that the cooling speed is varied into 20° C./second, 10° C./second, 5° C./second, 3.5° C./second, and 1° C./second by variously changing a profile of a reflow furnace, differential scanning calorimetry (DSC) characteristics of respective specimens obtained in the respective cooling conditions have been measured. Then, it has been proved that the slower the cooling speed is, the more the considerable low-melting-point phase occurs.

The cooling condition of the solder material when an electronic component is manufactured using the solder material can be set by manufacturing equipment such as the reflow furnace and a solder sealing device. However, although the cooling speed is expected to be fast as much as possible such that the low-melting-point phase is hard to occur, if load to the equipment is considered, there is a limit. Thus, the cooling speed is 5° C./second at the fastest, and preferably 3.5° C./second. Therefore, the solder material where the low-melting-point phase does not occur at such cooling speeds is preferred.

In such case, it has been proved that, in a composition of a solder material of this disclosure, especially when the content rate of In is properly set, even if the cooling speed after the solder material is melted is slowed to 5° C./second, and further to 3.5° C./second, the considerable low-melting-point phase does not substantially occur at a hardened product.

### 2. CONFIGURATION OF SOLDER MATERIAL

From the perception as described above, the solder material of this disclosure includes 25 to 45 mass % of Sn, 30 to 40 mass % of Sb, 3 to 8 mass % of Cu, 15 to 25 mass % of Ag, and 1.3 to 6 mass % of In (preferably 1.3 to 5 mass %, and more preferably 1.5 to 4 mass %). In the following, a description will be specifically given.

In this solder material, Sn has a role that governs a solidus temperature that is a temperature where the solder material starts melting. The content of Sn is determined corresponding a purpose of use from a range of 25 to 45 mass % (25 mass % or more, and 45 mass % or less).

Sb has a role that controls a eutectic point of this solder material. Specifically, for example, at this solder material including Ag and Cu, the eutectic point is likely to increase. However, if Sb is applied, the eutectic point can be reduced. However, if the content of Sb is excess, Sb recrystallizes to scatter in the melted solder, thus deteriorating a quality of the solder material. Therefore, considering them, the content of Sb is determined from a range of 30 to 40 mass % (30 mass % or more, and 40 mass % or less).

Cu has a role that accustoms a hardened product of this solder material. Here, to accustom means to strengthen binding of the respective metals in the solder material to one another. If the amount of Cu is excess, since a melting temperature of the solder material tremendously increases, and a hardness of the hardened product after soldering increases, it is not preferred. Therefore, considering them, the content of Cu is determined from a range of 3 to 8 mass % (3 mass % or more, and 8 mass % or less).

Ag has a role that keeps stability of bonding of the solder material. Here, good bonding stability means that the hardened product after soldering using this solder material has a high mechanical strength. More specifically, the good bonding stability means that, when a container is airtightly sealed to a lid member using this solder material at the electronic component such as a crystal resonator, a bonding strength of the container to the lid member is high. However, if the content of Ag is excess, crystallization of Ag is likely to occur inside the hardened product, and therefore wettability of the solder gets worse. Moreover, increase of the content of Ag causes a cost increase. If the content of Ag is excess, there is a property that the solidus temperature that is the temperature where the solder material starts melting is likely to be influenced by a temperature of a melting point of Sn. In other words, reduction of the amount of Ag can control decrease of the solidus temperature of this solder material. Therefore, considering them, the content of Ag is good to be 25 mass % or less, and preferably determined from a range of 15 to 25 mass % (15 mass % or more, and 25 mass % or less).

In has a role that governs a liquidus temperature that is a temperature where the solder material is completely melted. Specifically, as the content of In increases, a trend that the liquidus temperature increases is indicated. However, as the content of In increases, a trend that the liquidus temperature becomes unstable is indicated. On the other hand, if the content of In is too little, the wettability of the solder material decreases. Therefore, for example, bondability of the container to the lid member when airtightly sealing is deteriorated to decrease a sealing yield rate. As a specified matter, at this solder material, the low-melting-point phase is likely to occur in the hardened product as the cooling speed after melting slows. However, properly setting this content of In ensures effect that this low-melting-point phase is less likely to occur. That is, properly setting the content of In can enlarge a degree of freedom of the cooling condition in a work that cools and hardens the solder material. Therefore, considering these matters and a result of an experiment in working examples and comparative examples, which are described later, a content X of In is 1.3 mass %≦X≦6 mass %, preferably 1.3 mass %≦X≦5 mass %, and more preferably 1.5 mass %≦X≦4 mass %.

The solder material of this disclosure can further include other materials in addition to Sn, Sb, Cu, Ag, and In.

First, as a preferred form, Si (silicon) and Ti (titanium) can be included. Including Si and Ti makes a gradient of a differential scanning calorimetry curve steep. The reason is conceivable that applying Si and Ti makes crystal that constitutes the solder fine to make particles that constitute the solder fine, thus making change from solid to liquid apparent. If the contents of Si and Ti are too little, the above-described miniaturization of the particles cannot be obtained. If the contents of Si and Ti are excess, Si and Ti themselves are less likely to remain as the crystal. Therefore, the amounts of Si and Ti are determined considering them. According to the experiment by the inventors, the contents of Si and Ti are each good to be 0.1 mass % or less, and preferably 0.05 mass % or less. Ti is hard to have a property that is like to become dross. Thus, increase of the amount of Ti possibly increases viscosity of the solder material. Therefore, the content of Ti is, as described above, 0.1 mass % or less, preferably 0.05 mass % or less, and more preferably 0.03 mass % or less.

As described above, at the solder material of this disclosure including Si and Ti, the change from solid to liquid becomes apparent, thus further reducing a probability that melting of the solder material is insufficient and a probability that a part thought to have been secured with the solder material is peeled off without sufficiently hardening.

As another form of additional elements, the solder material of this disclosure may include, for example, one or a plurality of elements selected from Ni, Fe, Mo, Cr, Mn, Ge, and Ga in a range that does not exceed 1 mass % (in a case of a plurality of elements, in ranges that each do not exceed 1 mass %) to improve fluidity of the solder and to improve the mechanical strength of the solder material.

### 3. MANUFACTURING EXAMPLE OF SOLDER MATERIAL

The following describes an exemplary method for manufacturing the solder material of this disclosure. First, each of Sn, Sb, Cu, Ag, and In is individually pulverized using a known crusher such as a turbo mill, a roller mill, a centrifugal force pulverizer, and a pulverizer to obtain powder of each metallic material.

Next, the powder of the respective metallic materials manufactured as described above is weighted to each fulfill a predetermined content in this disclosure, specifically, the composition shown in Table 1 described below, and then, mixed.

Next, this mixture is melted, for example, in a heated crucible to form molten metal. Next, the molten metal is granulated, for example, by known centrifugal atomization. The centrifugal atomization continuously supplies the above-described molten metal in the crucible on a rotary disc that rotates at high speed to circumferentially atomize the molten metal by centrifugal force of the rotary disc. This atomized molten metal is cooled in a predetermined atmosphere to be hardened, thus obtaining microparticulated solder material. If a diameter of this microparticle is too large, printability on a substrate of solder paste that is generated gets worse. If the diameter of this microparticle is too small, wettability to an applied product of the solder paste gets worse when the solder paste is heated. Therefore, it is good to manage workmanship of the above-described processed product to manufacture respective microparticles such that each microparticles have a grain diameter whose average particle diameter is in a range of 5 μm to 50 μm at a sphere-equivalent diameter, using a known particle size distribution measurement method such as particle image measuring and zeta potential measuring.

The solder material of this disclosure, a paste-like solder material is obtained by mixing such a microparticulated solder material and a flux. As the flux used when the solder paste is constituted, for example, flux including tackifier resin such as rosin, a thixotropic agent, an activator, and a solvent can be used. Regardless of difference of degree of activity of the flux, various fluxes can be used.

### 4. EXEMPLARY ELECTRONIC COMPONENT

The following describes an exemplary electronic component manufactured using the paste-like solder material prepared as described above.

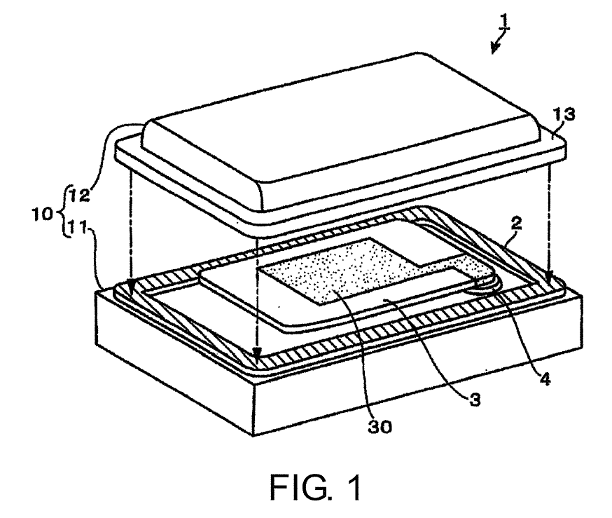

FIG. 1 is an exploded perspective view of a crystal resonator for describing a first exemplary crystal resonator as the electronic component. A crystal resonator 1 in this first example includes a substrate body 11, a lid member 12, a solder material 2 of this disclosure, and a crystal vibration chip 3. The substrate body 11 is, for example, made of ceramic and has a planar shape having a rectangular shape. The lid member 12 is connected to this substrate body 11. The solder material 2 bonds the substrate body 11 to the lid member 12. The lid member 12 has a cap shape by having a depressed portion whose peripheral area is an edge portion 13. The substrate body 11 and the lid member 12 constitute a container 10 that houses the crystal vibration chip 3. The crystal vibration chip 3 includes excitation electrodes 30 on the front and back, and is secured to the substrate body 11 at one end of the crystal vibration chip 3 with a conductive adhesive 4. At a position of the conductive adhesive 4 at the substrate body 11, a via-wiring (not illustrated) is disposed. Then, this via-wiring is connected to a mounting terminal (not illustrated) disposed on a back surface of the substrate body 11.

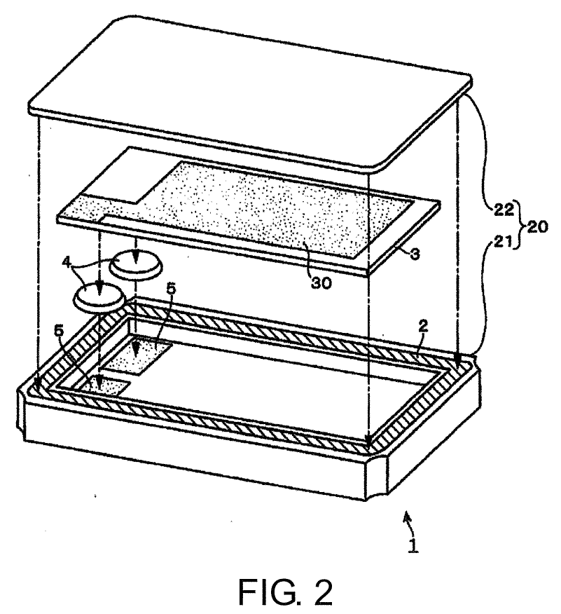

FIG. 2 is an exploded perspective view of a crystal resonator for describing a second exemplary crystal resonator as the electronic component. Main differences between this second exemplary crystal resonator and the first exemplary crystal resonator are a point that a substrate body 21 has a structure having a depressed portion that houses the crystal vibration chip 3 and a point that a lid member 22 has a flat plate shape. These substrate body 21 and lid member 22 constitute a container 20. Also in this second example, the substrate body 21 is bonded to the lid member 22 with the solder material 2 according to this disclosure. In FIG. 2, reference numerals 5 are pads that secure the crystal vibration chip 3. At positions of the pads 5 at the substrate body 21, a via-wiring (not illustrated) is disposed. Then, this via-wiring is connected to a mounting terminal (not illustrated) disposed on a back surface of the substrate body 21.

Bonding of the substrate body to the lid member of the crystal resonator is performed as follows. At around an edge portion of the substrate body 11 or 21 that mounts the crystal vibration chip 3, a paste of the solder material of this disclosure is applied, for example, by screen printing. Next, the lid member 12 or 22 is placed on this substrate body 11 or 21. Next, this specimen is set on a heatable sealing device, and then, the lid member and the substrate body are sealed by applying predetermined heat, for example, while applying pressure. A sealing atmosphere is a predetermined gas atmosphere such as a reduced-pressure atmosphere or a nitrogen atmosphere. Thus, the crystal resonator as the electronic component airtightly sealed with the solder material of this disclosure can be obtained. The solder material may be used in a state where the solder material is preliminary applied and melted on the lid member.

The electronic component to which this disclosure is applicable is not limited to the crystal resonator. This disclosure is applicable to various ones on which solder sealing is desired to be perfonned, such as a surface acoustic wave filter and a sensor.

The electronic component in this disclosure is not limited to the above-described crystal resonator or the like that has used the solder material of this disclosure as a sealing material. The electronic component in this disclosure also includes a substrate that mounts the electronic component. The substrate is constituted by soldering the electronic component such as the crystal resonator to a wiring board with the solder material of this disclosure. For example, the electronic component of this disclosure also includes an electronic component mounting substrate where the mounting terminal (not illustrated) of the crystal resonator and a connecting terminal on a wiring board (not illustrated) in FIG. 1 and FIG. 2 are connected one another with the solder material of this disclosure. Further, the electronic component of this disclosure also includes a module constituted by molding a substrate that mounts such electronic component with resin.

### 5. WORKING EXAMPLES AND COMPARATIVE EXAMPLES

5-1. Experiment by DSC Measurement

The following experiment of the working examples and the comparative examples has been performed to confirm an effect that can reduce remelting danger. The solder material of this disclosure has this effect.

Solder materials of the working examples and the comparative examples having compositions shown in Table 1 have been prepared by the above-described manufacturing method.

Next, each of the solder materials of these working examples and comparative examples have been melted at a temperature of 475° C., and then, cooled at a cooling speed of 5° C./second to be hardened. Here, the reason that has melted the solder materials at the temperature of 475° C. is for surely melting the respective solder materials of the working examples and the comparative examples. Therefore, this temperature is merely one example.

Next, on the respective hardened specimens, a differential scanning calorimetry has been perfoll ied. Then, a solidus temperature, a liquidus temperature, and a liquid phase rate and a solid phase rate at 280° C. for each specimen have been obtained. These results are shown in Table 1. A DSC device used in the measurement is Thermo Plus EVOII/DSC8230 (manufactured by Rigaku). The measurement has been performed by a method normalized in Japanese Industrial Standard Z3198-1. For the liquid phase rate and the solid phase rate, taking a whole peak area in the DSC measurement result as 100%, a peak area ratio at less than 280° C. is the liquid phase rate, and a peak area ratio at 280° C. or more is the solid phase rate. The reason that the temperature of 280° C. is set in calculation of the liquid phase rate and the solid phase rate is, since a melting point of a gold-tin alloy currently generally used is 280° C., for easily determining whether the solder material of this disclosure can assure a heat resistance equal to or more than a heat resistance of the gold-tin alloy or not.

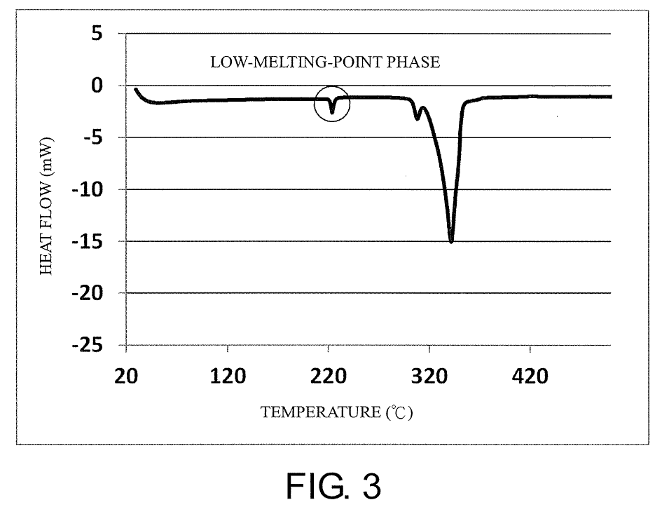

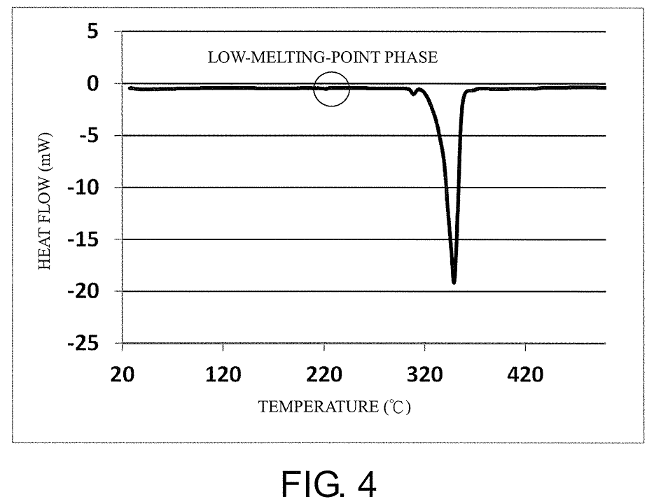

FIG. 3 illustrates a DSC characteristic diagram at a specimen of a comparative example 1 as an exemplary DSC measurement result of the comparative examples. FIG. 4 illustrates a DSC characteristic diagram at a specimen of a working example 1 as an exemplary DSC measurement result of the working examples. In FIG. 3 and FIG. 4, the horizontal axis is a temperature (° C.), and the vertical axis is a heat flow (mW).

As apparent from FIG. 3, in the case of the comparative example 1, an absorption peak of the low-melting-point phase at 222° C. was large. The above-defined liquid phase rate was 1.8%. For each specimen of comparative examples 2 and 3, as a characteristic diagram is omitted, similarly to the comparative example 1, the absorption peak of the low-melting-point phase was large, and as seen in Table 1, similarly to the comparative example 1, the liquid phase rate also exceed 1% as the results. As comparative examples 4, 5, and 6, as shown in Table 1, solder materials whose contents of In are 1 mass %, 1.3 mass %, and 0.5 mass % have been evaluated respectively. At respective specimens of these comparative examples 4, 5, and 6, the liquid phase rates have indicated small values: 0.1%, 0.2%, and 0.5%. However, at a sealing reliability evaluation in “5-2. Experiment at Electronic Component” described later, preferable results have not been indicated. Thus, the respective specimens of the comparative examples 4, 5, and 6 were out of range of this disclosure (details will be described below).

Meanwhile, as apparent from FIG. 4, in the case of the working example 1, the absorption peak of the low-melting-point phase did not substantially exist, and the liquid phase rate was 0.1%. Also for specimens of other working examples, although characteristic diagrams are omitted, similarly to the working example 1, the absorption peak of the low-melting-point phase did not substantially exist, and as seen from Table 1, similarly to the working example 1, the liquid phase rate is 0.7% at a maximum, and almost liquid phase rate are 0.5% or less.

Therefore, at the specimen of the working example, it is found that even if heat is applied again after melting and hardening, remelting is less likely to occur. That is, it is found that, even when the cooling speed in melting and hardening at the first time is set to 5° C./second, a feasible relatively fast speed, remelting in reheating can be prevented. Although a DSC characteristic diagram is omitted, at the solder materials of the respective working examples, even when the cooling speed after the solder material is melted is set to 3.5° C./second, similarly to the case where the cooling speed is 5° C./second, the low-melting-point phase does not substantially occur. This can be confirmed in the experiment by the inventors.

TABLE 1

| | Composition of | | | | | | | Solid | Liquid |
|---|---|---|---|---|---|---|---|---|---|
| | solder material | | | | | Solidus | Liquidus | phase | phase |
| | (mass %) | | | | | temperature | temperature | rate | rate |
| | Sn | Sb | Ag | Cu | In | (° C.) | (° C.) | (%) | (%) |
| Comparative example 1 | 37 | 35 | 17 | 5 | 6 | 222 | 373 | 98.2 | 1.8 |
| Comparative example 2 | 39 | 37 | 12 | 5 | 7 | 221 | 364 | 99.9 | 1 |
| Comparative example 3 | 38 | 36 | 13 | 5 | 8 | 213 | 433 | 98.8 | 1.2 |
| Comparative example 4 | 37 | 39 | 17 | 6 | 1 | 220 | 371 | 99.9 | 0.1 |
| Comparative example 5 | 37 | 37 | 19.7 | 5 | 1.3 | 219 | 374 | 99.8 | 0.2 |
| Comparative example 6 | 37 | 37 | 20.5 | 5 | 0.5 | 220 | 378 | 99.5 | 0.5 |
| Working example 1 | 37 | 35 | 21 | 5 | 2 | 219 | 374 | 99.9 | 0.1 |
| Working example 2 | 37 | 39 | 17 | 5 | 2 | 220 | 371 | 99.9 | 0.1 |
| Working example 3 | 37 | 35 | 19 | 5 | 4 | 221 | 377 | 99.7 | 0.3 |
| Working example 4 | 37 | 37 | 17 | 5 | 4 | 221 | 374 | 99.8 | 0.2 |
| Working example 5 | 45 | 33 | 15 | 3 | 4 | 215 | 355 | 99.3 | 0.7 |
| Working example 6 | 25 | 40 | 23 | 8 | 4 | 220 | 351 | 99.7 | 0.3 |
| Working example 7 | 30 | 40 | 20 | 7 | 3 | 217 | 379 | 99.6 | 0.4 |
| Working example 8 | 43 | 30 | 18 | 5 | 4 | 222 | 367 | 99.5 | 0.5 |
| Working example 9 | 40 | 34 | 19 | 4 | 3 | 220 | 385 | 99.4 | 0.6 |
| Working example 10 | 36 | 38 | 17 | 5 | 4 | 219 | 358 | 99.6 | 0.4 |
| Working example 11 | 39 | 34 | 18 | 6 | 3 | 221 | 347 | 99.6 | 0.4 |
| Working example 12 | 40 | 34 | 19 | 4 | 3 | 218 | 385 | 99.7 | 0.3 |
| Working example 13 | 37 | 37 | 19.5 | 5 | 1.5 | 219 | 372 | 99.8 | 0.2 |

5-2. Experiment at Electronic Component

The following describes a result that has confirmed the effect of this disclosure by the second exemplary crystal resonator described with reference to FIG. 2.

First, the second exemplary crystal resonators illustrated in FIG. 2, crystal resonators airtightly sealed using solder materials of working examples 13, 1, and 3, and the solder material of the comparative example 6, 4, 5, 1, 2, and 3, as the solder materials have been manufactured in 20 pieces for each case. That is, focusing on the contents of In (mass %), respective specimens have been manufactured using the solder materials corresponding to 0.5, 1, 1.3, 1.5, 2, 4, 6, 7, and 8. Next, sealing yield rates immediately after sealing, and yield rates after the specimens deteii lined to be quality items after sealing had been passed through a predetermined reflow furnace for several times have been each examined. A sealing quality determination immediately after sealing has been performed by microscopy of bonding condition of the substrate body 21 to the lid member 22, and a known He leakage test. Each quality determination after passing the specimens through the reflow furnace has been performed by the known He leakage test and a bubble leakage test. Reflow has been performed using a reflow furnace having a temperature profile that maintains a temperature of 210° C. or more for 80 seconds ±20 seconds, and maintains a temperature of 255° C. as a peak temperature for 30 seconds.

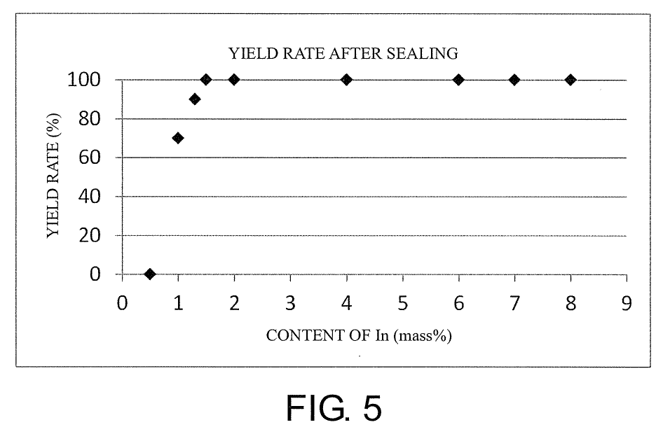

FIG. 5 is a drawing illustrating an evaluation result immediately after sealing the crystal resonators of the working example and the comparative example. The horizontal axis represents the content of In (mass %) and, the vertical axis represents the yield rate immediately after sealing. As seen from FIG. 5, the yield rate is 0% when the content rate of In is 0.5 mass %, the yield rate is 70% when the content rate of In is 1 mass %, the yield rate is 90% when the content rate of In is 1.3 mass %, and the yield rate is 100% when the content rate of In is 1.5 mass % to 8 mass %.

Table 2 shows each yield rate that the quality item after sealing has been passed through the reflow furnace for several times. As seen from Table 2, when the content rate of In is 1.5 mass % or more, and 4 mass % or less, even though the number of reflow is increased, the yield rate is maintained at 100%. Even when the content rate of In is 1.3 mass % or more, and 6 mass % or less, the yield rate is ensured to some extent. Thus, it can be said to be applicable to a product by proper manufacturing condition or the like. In contrast, at the specimen whose content of In exceeds 7 mass %, even after the reflow at the first time, the failure occurs. As the number of reflow increases, the failure occurs. When the content of In is 6 mass %, after the reflow at the fifth time, the failure occurs.

Examining these results in FIG. 5 and Table 2, when the content of In is 1.3 mass % or more, and 6 mass % or less, the effect of this disclosure is obtained. Preferably, the content of In is 1.3 mass % or more, and 5 mass % or less. More preferably, the content of In is 1.5 mass % or more, and 4 mass % or less.

TABLE 2
Relation between content of In and yield rate (%) after each reflow

| | Content of In (mass %) | | | | | | |
|---|---|---|---|---|---|---|---|
| The number of reflow | 1.3 | 1.5 | 2 | 4 | 6 | 7 | 8 |
| After first reflow | 100 | 100 | 100 | 100 | 100 | 95 | 40 |
| After third reflow | 100 | 100 | 100 | 100 | 100 | 50 | 0 |
| After fifth reflow | 100 | 100 | 100 | 100 | 90 | 10 | |
| After seventh reflow | 100 | 100 | 100 | 100 | 45 | 0 | |
| After tenth reflow | 100 | 100 | 100 | 100 | 10 | | |

5-3. Confirmatory Experiment of Wettability

Using the solder materials of the comparative example and the working example used in the above-described sealing experiment, according to a method normalized in Japanese Industrial Standard Z3284-4:204, evaluation of solder wettability has been performed.

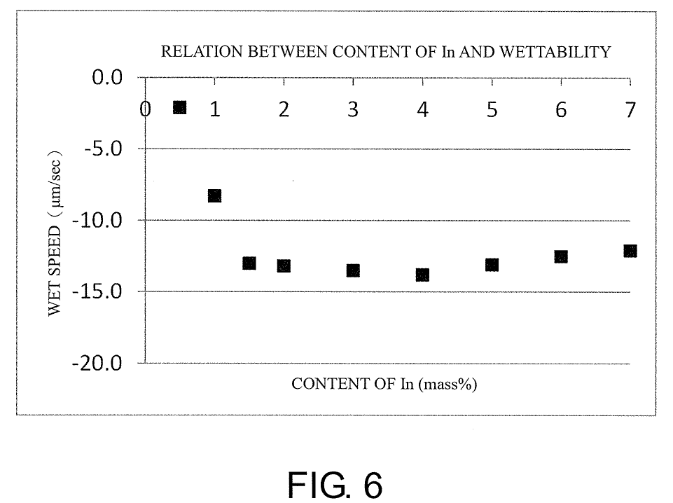

FIG. 6 is a drawing illustrating this result. The horizontal axis represents the content of In (mass %). The vertical axis represents a wet speed (μm/sec) specified in the above-described Japanese Industrial Standard.

From this result in FIG. 6, the wettability is poor, −2.1 when the content of In is 0.5 mass %. When the content of In is 1 mass %, the wettability is improved more than three times compared with the case where the content of In is 0.5 mass %. When the content of In is 1.5 mass % or more, the wettability is further improved to be almost maintained at a practically satisfactory level.

Therefore, also from the aspect of wettability, a lower limit of the content of In is good to be 1.3 mass %, and more preferably 1.5 mass %. If the wettability is poor, melting and bonding of the solder, for example, when the crystal resonator is airtightly sealed is not properly performed, thus reducing the yield rate after sealing. Also in the context of the results in FIG. 5 and Table 2, the lower limit of the content of In is good to be 1.3 mass %, and more preferably 1.5 mass %.

5-4. Experimental Result of Addition of Si and Ti

The following describes an experimental result where Si and Ti have been added as additional trace elements. At the solder material of the working example 1, the content of Ag is reduced by 0.01 mass %, and alternatively, 0.05 mass % of Si and 0.05 mass % of Ti are included, thus adjusting a solder material of a working example 15.

Next, this material is, similarly to the above-described working examples, melted at the temperature of 475° C., and then, cooled at the cooling speed of 5° C./second to be hardened. Next, on the hardened specimen, the differential scanning calorimetry has been performed.

The solder material including Si and Ti has a heat flow peak larger than that of the solder material without Si and Ti, and moreover, has a gradient of a differential scanning calorimetry curve steeper than that of the solder material without Si and Ti. This means that the change from solid to liquid becomes apparent. Thus, it can be said that melting and hardening of the solder material can be more properly performed.

To embody this disclosure, it is preferable that the content of Ag is 15 to 25 mass %. The content of In is preferably 1.3 to 5 mass %, and more preferably 1.5 to 4 mass %. A cooling condition after the solder material of this disclosure is heated and melted is preferably a cooling speed faster than a cooling speed of 3.5° C./second, and more preferably a cooling speed faster than a cooling speed of 5° C./second. Such cooling speed can reduce possibility that the low-melting-point phase occurs at a hardened product.

According to the solder material of this disclosure, the occurrence of the low-melting-point phase after hardening can be reduced, thus ensuring prevention of the above-described trouble even if the heat reaches, for example, the electronic component airtightly sealed and connected to the substrate using this solder material. Therefore, this can provide an inexpensive solder material that has high reliability, and matched the request for lead-free.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A solder material, comprising:
25 to 45 mass % of Sn;
30 to 40 mass % of Sb;
3 to 8 mass % of Cu;
25 mass % or less of Ag; and
1.3 to 6 mass % of In.

2. A solder material, comprising:
25 to 45 mass % of Sn;
30 to 40 mass % of Sb;
3 to 8 mass % of Cu;
25 mass % or less of Ag; and
1.3 to 5 mass % of In.

3. A solder material, comprising:
25 to 45 mass % of Sn;
30 to 40 mass % of Sb;
3 to 8 mass % of Cu;
25 mass % or less of Ag; and
1.5 to 4 mass % of In.

4. The solder material according to claim 1, wherein a content of Ag is 15 to 25 mass %.

5. The solder material according to claim 1, further comprising:
0.1 mass % or less of Si; and
0.1 mass % or less of Ti.

6. The solder material according to claim 1, wherein
the solder material is a paste-like solder material which is obtained by mixing a microparticulated solder material and flux.

7. The solder material according to claim 1, wherein
the solder material is processed into a foil shape and is subsequently punched a preform.

8. An electronic component having an airtight sealing structure, comprising:
the solder material according to claim 1 used as an airtight sealing material.

9. An electronic component, comprising:
a substrate body and a lid member that constitute a container, wherein
the substrate body is bonded to the lid member with the solder material according to claim 1.

10. An electronic component, comprising:
a container that contains an electronic element; and
a wiring board mounted on the container, wherein
the solder material according to claim 1 is used as a connection material between the container and the wiring board.

11. An electronic component that has a module structure, wherein
the electronic component according to claim 8 is molded with resin.
